(19) United States
(12) Patent Application Publication
(10) Pub. No.: US 2009/0179254 A1
(43) Pub. Date: Jul. 16, 2009

(54) Memory Device With Improved Performance And Method Of Manufacturing Such A Memory Device

(75) Inventors: Robertus Theodorus Franciscus Van Schaijk, Eindhoven (NL); Pablo Garcia Tello, Leuven (BE); Michiel Slotboom, Oss (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/067,491

(22) PCT Filed: Sep. 13, 2006
(86) PCT No.: PCT/IB2006/053262

§ 371 Date: Dec. 2, 2008

(30) Foreign Application Priority Data
Sep. 23, 2005 (EP) 05108804.5

(51) Int. Cl. H01L 29/792; H01L 21/336

(52) U.S. Cl. 257/324; 438/287; 257/E29.309; 257/E21.423

(57) ABSTRACT

Non-volatile memory device on a semiconductor substrate, comprising a semiconductor base layer, a charge storage layer stack, and a control gate; the base layer comprising source and drain regions and a current-carrying channel region being positioned in between the source and drain regions; the charge storage layer stack comprising a first insulating layer, a charge trapping layer and a second insulating layer, the first insulating layer being positioned above the current-carrying channel region, the charge trapping layer being above the first insulating layer and the second insulating layer being above the charge trapping layer; the control gate being positioned above the charge storage layer stack; the charge storage layer stack being arranged for trapping charge in the charge trapping layer by direct tunneling of charge carriers from the current-carrying channel region through the first insulating layer, wherein the current-carrying channel region is a p-type channel for p-type charge carriers, and the material of at least one of the current-carrying channel region and/or the source and drain regions is in an elastically strained state.

### FIELD OF THE INVENTION

The present invention relates to a non-volatile memory device. Also, the present invention relates to a method of manufacturing such a non-volatile memory device.

### BACKGROUND OF THE INVENTION

The present industry standard for non-volatile semiconductor memories is based on devices which relate to the effect of electric charge stored on a floating gate. During a write (program) action, electric charge is stored into the floating gate. In such non-volatile semiconductor memory devices, charge storage in the floating gate is based on a mechanism of hot-electron injection or Fowler-Nordheim tunneling. Under the control of a control gate, electrons which flow, with sufficient energy, through a current-carrying channel between source and drain regions can pass a dielectric layer between a current-carrying channel and the floating gate, and can enter into the floating gate as stored electric charge.

Due to issues regarding the scaling of these floating gate-based devices to smaller sizes, coming generations of non-volatile semiconductor memories are expected to use a modified charge storing layer stack that consists of a charge trapping layer which is located between a bottom and top insulating layer. For example, such a charge storage layer stack comprises a bottom silicon dioxide layer, a charge trapping silicon nitride layer and a top silicon dioxide layer, also known as an ONO stack.

In these non-volatile semiconductor devices having an ONO layer stack, charge can be stored in the silicon nitride layer by a mechanism of direct tunneling of electrons (Fowler-Nordheim) through the bottom silicon dioxide layer (tunnel-oxide layer) from the current-carrying channel to the silicon nitride layer. Due to the high mobility of electrons in the n-channel, relatively high read currents can be obtained which are adequate for many applications.

The charge trapping properties of the silicon nitride layer allow for downscaling the thickness of the tunnel-oxide layer, which may result in lower program/erase voltages.

Patent application US 2004/0251490A1 discloses a SONOS (Semiconductor Oxide-Nitride-Oxide Semiconductor) memory device based on nMOS technology (n-type MOS: metal-oxide-semiconductor). This memory device uses electrons from an n-type channel as carriers for storing data in the silicon nitride layer during the write action.

Disadvantageously, nMOS SONOS memory devices suffer from a phenomenon known as erase saturation.

During an erase action to neutralize a charge of electrons in the silicon nitride layer, holes can tunnel through the bottom insulating silicon dioxide layer from the channel region to the silicon nitride layer and recombine with the trapped electrons in the silicon nitride layer. Due to the relatively high barrier for holes compared with the barrier for electrons, the tunnel current is lower during the erase action. During this action the threshold voltage of the memory device increases and consequently the electric field across the silicon nitride layer increases too. Also, this results in a higher electric field across the top insulating layer of the ONO stack, which causes electrons to tunnel from the control gate through the top insulating layer to the silicon nitride layer to counterbalance the holes entering the silicon nitride layer. At this point, the threshold voltage does not change anymore.

However, during such an erase action, relatively large currents flow through the bottom and top insulating layer, respectively. These currents may deteriorate the quality of the respective insulating layer by creating local defects (deep traps) which can cause a defect-related charge being permanently trapped in the charge storage stack. The number of defects (and the corresponding trapping of defect-related charge) substantially increases with each erase action and causes the level of the threshold voltage to increase gradually over the lifetime of the device. FIG. 1 shows the threshold voltage for write (program) Vp and the threshold voltage for erase Ve in a prior art nMOS SONOS memory device as a function of program/erase cycles PE.

Clearly, the change of the threshold voltage has an harmful effect on read actions of the memory device. Since the threshold voltage defines the memory state, or bit value, of the memory device (being either ‘0’ or ‘1’, depending on the actual voltage of the memory device being below or above the threshold voltage), a change of the permanently trapped defect-related charge will adversely affect the detection of the bit value.

As a result, nMOS SONOS memory devices cannot obtain a threshold voltage below 0V. A useful threshold voltage window would be between about 0.5 V and 3 V, with a read voltage of typically about 2 V. Such a value for the read voltage is relatively high, considering that the supply voltage of many present CMOS applications is typically lower. FIG. 2 shows the threshold voltage Vt for the erase state in a prior art nMOS SONOS memory device as a function of the gate stress time for a typical read voltage. As illustrated by FIG. 2, the high read voltage disadvantageously causes a severe gate stress on the erased state of the memory device, which again results in an increase of the threshold voltage during lifetime.

### SUMMARY OF THE INVENTION

It is an object of the present invention to provide a memory device with a charge trapping layer which is practically unaffected by an increase of the threshold voltage caused by erase saturation and/or gate stress, and at the same time maintains the abovementioned relatively high read currents.

The present invention relates to a non-volatile memory device on a semiconductor substrate, comprising a semiconductor base layer, a charge storage layer stack, and a control gate;

the base layer comprising source and drain regions and a current-carrying channel region being positioned in between the source and drain regions;

the charge storage layer stack comprising a first insulating layer, a charge trapping layer and a second insulating layer, the first insulating layer being positioned above the current carrying channel region, the charge trapping layer being above the first insulating layer and the second insulating layer being above the charge trapping layer;

the control gate being positioned above the charge storage layer stack;

the charge storage layer stack being arranged for trapping charge in the charge trapping layer by direct tunneling of charge carriers from the current carrying channel region through the first insulating layer, wherein the current carrying channel region is a p-type channel for p-type charge carriers, and the material of at least one of the current-carrying channel region and the source and drain regions is in an elastically strained state.

Advantageously, by using a strained p-channel as a current-carrying channel, the memory device according to the present invention has an erase action which is reversed with respect to the memory device of the prior art. Now, electrons may tunnel from the p-channel to the charge storage layer to recombine with holes trapped in the charge storage layer. Although the threshold voltage will become more negative during the erase action and before reaching an equilibrium holes may tunnel from the control gate on the top insulating layer to recombine with electrons from the channel, this effect could lead to an erase saturation, but in practice this will not occur since the (absolute value of the) threshold voltage in the memory of the present invention at which the erase saturation would occur is typically much higher and will not be reached in normal operation. The straining of the lattice of the material in the p-channel causes an increase of the mobility of the current carrier (i.e., holes) to allow that advantageously the read current of the memory device of the present invention is substantially on par with that of nMOS SONOS memory devices of the prior art.

Moreover, the present invention relates to a method of manufacturing a non-volatile memory device on a semiconductor substrate, comprising a base layer, a charge storage layer stack, and a control gate; the base layer comprising source and drain regions and a current-carrying channel region being positioned in between the source and drain regions; the charge storage layer stack comprising a first insulating layer, a charge trapping layer and a second insulating layer, the first insulating layer being positioned above the current carrying channel region, the charge trapping layer being above the first insulating layer and the second insulating layer being above the charge trapping layer;

the control gate being positioned above the charge storage layer stack;

the charge storage layer stack being arranged for trapping charge in the charge trapping layer by direct tunneling of charge carriers from the current carrying channel region through the first insulating layer, wherein the method comprises:

creating a p-type channel for p-type charge carriers as the current carrying channel region, and

creating a state of elastic strain in the material of at least one of the current carrying channel region and the source and drain regions.

Also, the present invention relates to a memory array comprising at least one non-volatile memory device as described above.

Moreover, the present invention relates to a semiconductor device comprising at least one non-volatile memory device as described above.

### BRIEF DESCRIPTION OF DRAWINGS

For the purpose of teaching of the invention, preferred embodiments of the devices and method of the invention are described below. It will be appreciated by the person skilled in the art that other alternative and equivalent embodiments of the invention can be conceived and reduced to practice without departing from the true spirit of the invention, the scope of the invention being limited only by the appended claims.

FIG. 1 shows the threshold voltage for write (program) and for erase in a prior art nMOS SONOS memory device as a function of program/erase cycles;

FIG. 2 shows the threshold voltage for the erase state in a prior art nMOS SONOS memory device as a function of the gate stress time for a typical read voltage;

FIG. 3 shows a SONOS memory device according to the present invention;

FIG. 4 shows threshold voltages for program and erase for a prior art nMOS SONOS memory device and the SONOS memory device according to the present invention;

FIG. 5 shows a cross sectional view of a SONOS memory device manufactured according to a first method;

FIG. 6 shows a cross sectional view of a SONOS memory device manufactured according to a second method, and

FIG. 7 shows a cross sectional view of a SONOS memory device manufactured according to a third method.

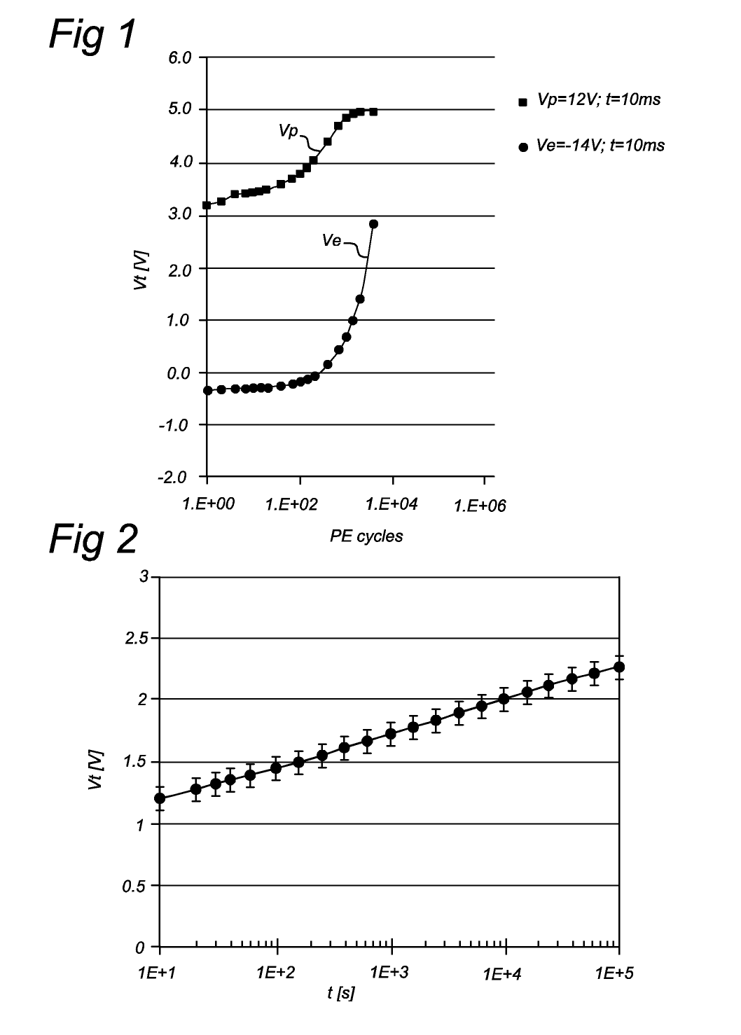

### DETAILED DESCRIPTION OF EMBODIMENTS

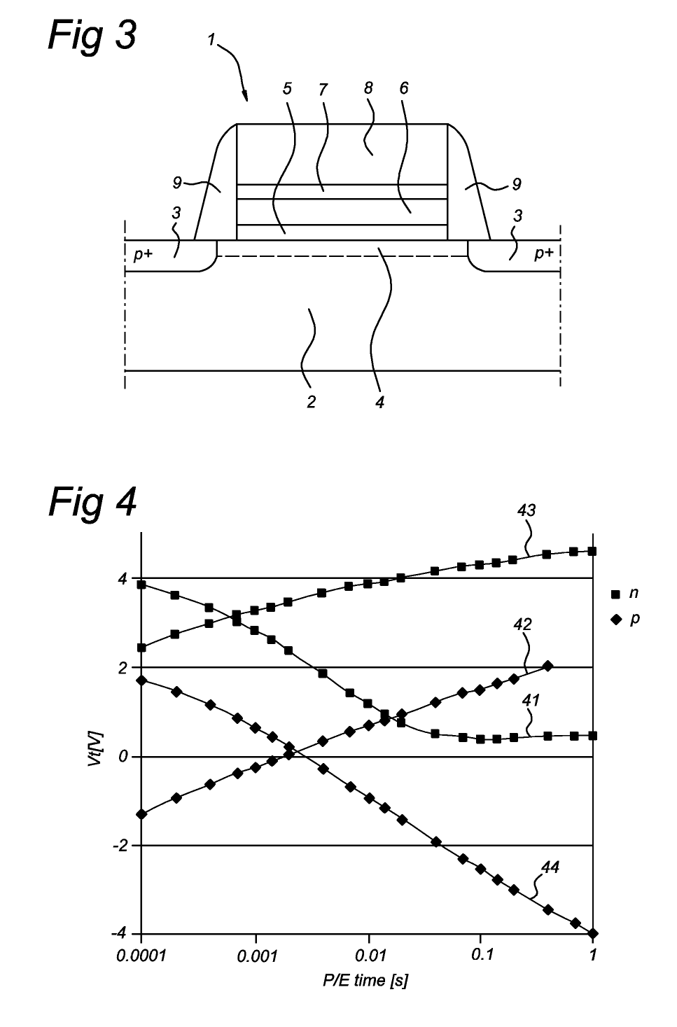

FIG. 3 shows a SONOS memory device 1 according to the present invention.

On a base layer 2, which is a monocrystalline n-type semiconductor, p-type source and drain regions 3 are located. Between the (highly doped) p+ source and drain regions 3 a first insulating layer 5 is located. A charge trapping layer 6 is positioned on top of the first insulating layer 5. On top of the charge trapping layer 6 a second insulating layer 7 is positioned. A control gate layer 8 is located above the second insulating layer 7.

First insulating layer 5, charge trapping layer 6 and second insulating layer 7 form the charge storage layer stack 5, 6, 7.

The side walls of first insulating layer 5, charge trapping layer 6, second insulating layer 7 and control gate layer 8 are covered by an insulating spacer 9. Below the first insulating layer 5, in the base layer 2, a p-type channel region 4 can be formed during operation of the device 1.

For a SONOS memory device 1 based on silicon as the semiconductor, in the coming 65 nm generation, the channel length of the p channel will be about 100 nm. Typically, the first insulating (silicon dioxide) layer 5 has a thickness of about 1.5-3 nm, typically 2 nm. The thickness of the charge trapping (silicon nitride) layer 6 is in a range of about 4-8 nm, typically 6 nm. The second insulating (silicon dioxide) layer 7 has a thickness in a range of about 4-12 nm, typically 8 nm. The thickness of the control gate (poly-Silicon) layer 8 is within a range of about 30-150 nm, typically 100 nm.

In this p-type SONOS memory device 1, holes in the p-channel region 4 carry the current. During programming, holes in the p-channel region 4 with sufficient energy can (under the control of a program voltage Vp on the control gate 8) cross the first insulating layer 5 by means of direct tunneling, enter the charge trapping layer 6 and create a trapped charge.

During the read operation, a read voltage Vr is applied to the control gate 8. The magnitude of the trapped charge determines, during a read operation, whether a read current can be detected betweens source and drain regions 3. Depending on the definition of the read current as measured, a bit value of either ‘0’ or ‘1’ is present in the SONOS memory device 1.

During an erase of the charge trapping layer 6, the voltage for erase Ve on the control gate is set to such a value that electrons from the channel 4 can tunnel through the first insulating layer 5 and recombine with the positive trapped charge in the charge trapping layer 6.

Note that in the p-type SONOS memory device 1 according to the present invention, although the threshold voltage will become more negative during the erase action and before reaching an equilibrium, holes may tunnel from the control gate on the top insulating layer to recombine with electrons from the channel, this effect could lead to an erase saturation, but in practice this will not occur since the (absolute value of the) threshold voltage in the memory device 1 remains too small for generating holes in the control gate 8 which may tunnel through the second insulating layer 7.

FIG. 4 shows threshold voltages for program and erase for a prior art nMOS SONOS memory device and the SONOS memory device according to the present invention as a function of the program/erase time PE. In the prior art nMOS SONOS memory device, the threshold voltage for erase (line 41) shows a clear saturation for times above about 0.07 s. In the SONOS memory device according to the present invention no erase saturation in the threshold voltage for erase (line 42) is visible.

A threshold voltage for program for a prior art nMOS SONOS memory device is shown by line 43. A threshold voltage for program for the SONOS memory device according to present invention is shown by line 44.

Note that for the SONOS memory device according to present invention the definition of the threshold voltage is chosen negatively in comparison to the SONOS memory device of the prior art.

The p-type SONOS memory device 1 is intrinsically arranged to prevent erase saturation. This allows to use a read voltage between zero voltage and supply voltage which advantageously avoids the requirement of boosting the supply voltage to a higher read voltage level. This results in operation at relatively lower power and in a simpler memory array layout with smaller memory peripheral circuits (i.e., without boost circuit) compared with prior art nMOS SONOS memory devices.

It is known that for a given semiconductor material the mobility of holes is lower than that of electrons: in a p-type device the current is lower than in an n-type device of the same semiconductor base material. Further, the mobility of holes is known to depend on the elastic stress/strain state of the semiconductor material. By elastic deformation of the semiconductor material lattice, the mobility of holes in the semiconductor can be enhanced. Depending on the actual semiconductor material, either a tensile or compressive strain state (along the direction of the channel) may be applicable.

Therefore, in the SONOS memory device 1 of the present invention, to enhance the mobility of the holes and to increase the current in the p-channel 4, the lattice of the p-channel material 2 is strained.

The introduction of elastic strain in the channel region can be done in various ways dependent upon the specific non-volatile memory device to be manufactured.

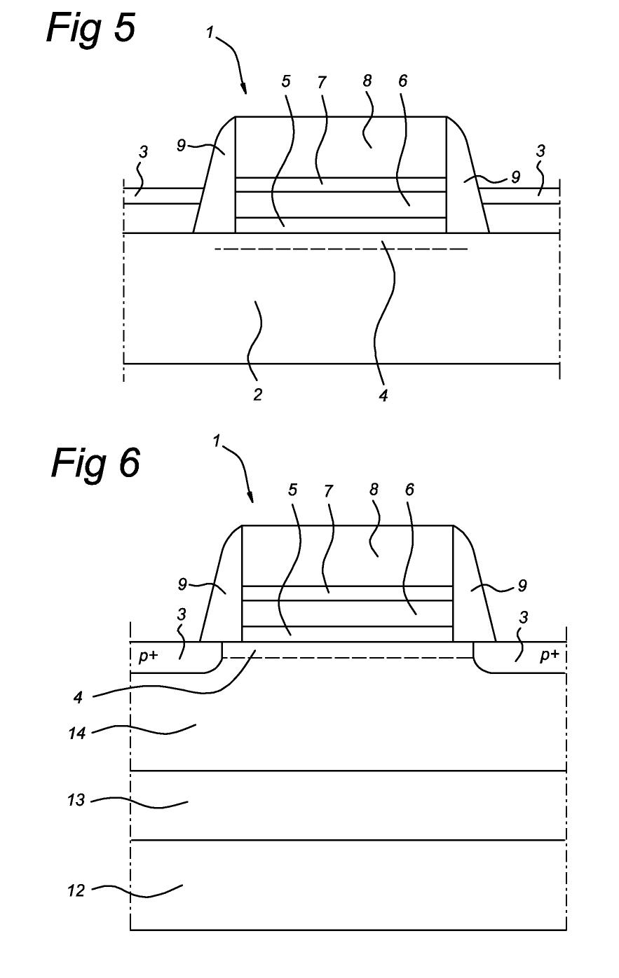

FIG. 5 shows a cross-sectional view of a SONOS memory device 1 manufactured according to a first method. The first method of manufacturing comprises the introduction of elastic strain locally in the source and drain regions 3. This local strain also influences the lattice of the p-channel. In this first method, firstly the charge storage layer stack 5, 6, 7, 8 is defined by deposition of the individual layers to form a stack of blanket layers. Then, a lithographic procedure to pattern the stack of blanket layers into discrete charge storage layer stacks is carried out. Spacers 9 are formed at the sidewalls of each discrete stack 5, 6, 7, 8. Then, in the region of the base layer 2, possibly after etching the base layer 2, an epitaxial SiGe layer 10 is grown. By varying the Ge content during the growth of the layer 10, the lattice parameter of the top surface of the epitaxial layer 10 can be tuned to a desired value. The tuning of the lattice parameter during growth of an epitaxial SiGe layer is known to the skilled person. By the tuning of the lattice parameter of the SiGe layer 10, the lattice parameter of the epitaxial silicon is modified to introduce elastic strain, either compressive or tensile. In the epitaxial SiGe layer 10 the p-type source and drain regions 3 are defined. After silicidation of source and drain regions 3, a passivation layer (not shown) may be formed in which contacts with source and drain regions 3 and control gate 8 can be formed, as known to persons skilled in the art. The passivation layer will typically have a thickness in the range of 250-500 nm.

The width of the spacer 9 is between about 30 nm and about 100 nm. The thickness of the SiGe layer 10 is between about 20 nm and about 100 nm.

FIG. 6 shows a cross-sectional view of a SONOS memory device 1 manufactured according to a second method. The second method of manufacturing comprises the introduction of elastic strain globally in the source and drain regions 3 and the p-channel region 4.

On a silicon surface of a substrate layer 12 an epitaxial SiGe layer 13 is grown. Again, by varying the Ge content during the growth of the layer 13, the lattice parameter of the top surface of the epitaxial layer 13 can be tuned to a desired value. Next, on the top surface of the SiGe layer 13 a strained base layer 14 of n-type epitaxial silicon is grown. By the tuning of the lattice parameter of the SiGe layer 13, the lattice parameter of the strained epitaxial silicon 14 is modified to introduce elastic strain, either compressive or tensile. Next, the SONOS memory device 1 is defined on top of the strained base layer 14. The charge storage layer stack 5, 6, 7, and control gate 8 are defined by deposition of the individual layers 5, 6, 7, 8 to form a stack of blanket layers. Then, a lithographic procedure to pattern the stack of blanket layers into discrete charge storage layer stacks is carried out. Spacers 9 are formed at the sidewalls of each discrete charge storage layer stack 5, 6, 7, and control gate 8. Then, in the region of the strained base layer 2, adjacent to the spacers 9, the source and drain regions 3 are defined. Subsequently, a passivation layer (not shown) may be formed in which contacts (not shown) with source and drain regions 3 and control gate 8 can be formed, as known to persons skilled in the art.

The SiGe layer 13 has a thickness between about 100 nm and about 1 μm. The strained epitaxial silicon layer 14 has a thickness between about 5 nm and about 20 nm, typically 10 nm.

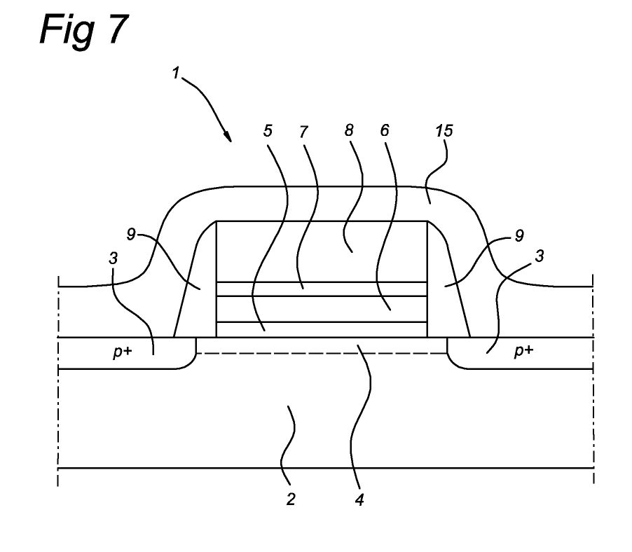

FIG. 7 shows a cross-sectional view of a SONOS memory device 1 manufactured according to a third method. The third method of manufacturing comprises the introduction of elastic strain locally in the source and drain regions 3 and the p-channel region 4 by using stress-inducing elements (stress-liners) as explained below.

First, a SONOS memory device 1 as described in FIG. 3 is created.

Then, in a subsequent processing step a stress-liner layer 15 is deposited over the source and drain regions 3 and over the region comprising the charge storage stack 5, 6, 7. The stress-liner layer can be patterned using known lithographic processing techniques. Moreover, it is conceivable that the stress-liner layer 15 is positioned only above either the source and drain regions 3 or the region of the charge storage stack 5, 6, 7.

The stress-liner layer 15 exerts a stress on (parts of) the SONOS memory device 1, which induces elastic strain in the p-channel region 4 and/or the source and drain regions 3.

The magnitude and sign of the stress in the stress-liner layer 15 may be adjustable: depending on the stress in the stress liner 15 either a tensile or a compressive strain may be generated in the p-channel region 4 and/or the source and drain regions 3.

The stress-liner layer 15 may comprise silicon nitride. Silicon nitride can be deposited by means of a low pressure chemical vapor deposition process (LPCVD). It is known that the stress within the silicon nitride of the stress-liner layer 15 can be tuned between, say, −1.0 and 1.0 GPa by selecting appropriate deposition process parameters.

It is also conceivable that tuning the stress in the stress-liner 15 is achieved by an appropriate choice of stress-liner material(s) with a suitable growth-related intrinsic stress.

The stress-liner layer 15 may have a thickness in the range of about 50-200 nm.

Due to the possibility of tuning the stress state of the stress-liner, the third method may provide first stress-liners specifically tuned for p-type SONOS memory devices (by using a first mask) and second stress-liners specifically tuned for n-type non-volatile (SONOS) memory devices (by using a second mask). Thus, specific tuning of the mobility of charge carriers in p-type channel and n-type channel memory devices on the same substrate can be achieved.

After creating the stress-liner layer(s) 15, a passivation layer (not shown) may be formed in which contacts (not shown) to source and drain regions 3 and control gate 8 can be formed, as known to persons skilled in the art.

The charge storage layer stack 5, 6, 7 may comprise as the first and second insulating layers 5, 7 either silicon dioxide or a high-K material. For the high-K material use may be made of, for example, Hafnium-oxide HfO₂, Hafnium-silicate HfₓSi₁₋ₓO₂ (0≦:x≦1), Hafnium-silicate-nitride HfSiON, Aluminum-oxide Al₂O₃ and Zirconium-oxide ZrO₂. The charge trapping layer 6 may be silicon nitride.

Suitable deposition processes for such materials to create a charge storage stack are known in the art.

The semiconductor base layer 2; 14 may consist of silicon or any other suitable semiconductor material.

In a further embodiment, the base layer 2 may also comprise n-doped germanium, with the first and second insulating layers 5, 7 being insulating layers of high-K material, and the charge trapping layer being a silicon nitride layer. In this embodiment the straining of the lattice of the source and drain 3 and/or the p-channel region 4 is preferably achieved by one or more stress-liner layers.

The SONOS memory device 1 according to the present invention can be integrated into a memory array which comprises a plurality of such SONOS memory devices or into any other semiconductor circuit device.

1. Non-volatile memory device, on a semiconductor substrate, comprising a semiconductor base layer, a charge storage layer stack, and a control gate;
the base layer comprising source and drain regions and a current-carrying channel region being positioned in between the source and drain regions;
the charge storage layer stack comprising a first insulating layer, a charge trapping layer and a second insulating layere, the first insulating layer being positioned above the current carrying channel region, the charge trapping layer being above the first insulating layer and the second insulating layer being above the charge trapping layer;
the control gate being positioned above the charge storage layer stack;
the charge storage layer stack being arranged for trapping charge in the charge trapping layer by direct tunneling of charge carriers from the current carrying channel region through the first insulating layer, wherein
the current carrying channel region is a p-type channel for p-type charge carriers, and
the material of at least one of the current carrying channel region and the source and drain regions is in an elastically strained state.

2. Non-volatile memory device on a semiconductor substrate according to claim 1, wherein the base layer comprises a lower SiGe layer.

3. Non-volatile memory device on a semiconductor substrate according to claim 2, wherein the base layer comprises an upper Si layer.

4. Non-volatile memory device on a semiconductor substrate according to claim 2, wherein the source and drain regions are positioned in the lower SiGe layer.

5. Non-volatile memory device on a semiconductor substrate according to claim 3, wherein the source and drain regions are positioned in the upper Si layer.

6. Non-volatile memory device on a semiconductor substrate according to claim 1, wherein the material of the first insulating layer comprises one of silicon dioxide and a high-K material.

7. Non-volatile memory device on a semiconductor substrate according to claim 1, wherein the material of the second insulating layer comprises one of silicon dioxide and a high-K material.

8. Non-volatile memory device on a semiconductor substrate according to claim 1, wherein the material of the charge trapping layer comprises silicon nitride.

9. Non-volatile memory device on a semiconductor substrate according to claim 1, wherein the base layer consists of Si or Ge.

10. Non-volatile memory device on a semiconductor substrate according to claim 1, wherein the non-volatile memory device comprises a stress-liner layer, the stress-liner layer being on top of at least one of the source and drain regions and the control gate.

11. Non-volatile memory device on a semiconductor substrate according to claim 10, wherein the stress-liner layer is a silicon nitride layer of which a stress state is tunable during deposition.

12. Non-volatile memory device on a semiconductor substrate according to claim 9, wherein the first insulating layer comprises a high-K material.

13. Non-volatile memory device on a semiconductor substrate according to claim 1, wherein a high-K material comprises one of Hafnium-oxide, Hafnium-silicate, Hafnium-silicate-nitride, Aluminum-oxide and Zirconium-oxide.

14. Non-volatile memory device on a semiconductor substrate, according to claim 1, wherein in use, the read voltage is between zero voltage and a supply voltage level.

15. Memory array comprising at least one non-volatile memory device according to claim 1.

16. Semiconductor device comprising at least one non-volatile memory device according to claim 1.

17. Method of manufacturing a non-volatile memory device on a semiconductor substrate, comprising a base layer, a charge storage layer stack, and a control gate; the base layer comprising source and drain regions and a current-carrying channel region being positioned in between the source and drain regions; the charge storage layer stack comprising a first insulating layer, a charge trapping layer and a second insulating layer, the first insulating layer being positioned above the current carrying channel region, the charge trapping layer being above the first insulating layer and the second insulating layer being above the charge trapping layer;
the control gate being positioned above the charge storage layer stack;
the charge storage layer stack being arranged for trapping charge in the charge trapping layer by direct tunneling of charge carriers from the current carrying channel region through the first insulating layer, wherein the method comprises:
creating a p-type channel for p-type charge carriers as the current-carrying channel region, and
creating a state of elastic strain in the material of at least one of the current-carrying channel region and the source and drain regions.

18. Method according to claim 17, wherein the creation of the state of elastic strain in the material of at least one of the current carrying channel region and the source and drain regions comprises the growing of a lower SiGe layer by a process of epitaxial growth.

19. Method according to claim 17, wherein the creation of the state of elastic strain in the material of at least one of the current-carrying channel region and the source and drain regions comprises the growing of a lower SiGe layer and an upper Si layer by a process of epitaxial growth.

20. Method according to claim 18, wherein either the lower SiGe layer or the lower SiGe layer and the upper Si layer are grown locally in the source and drain regions.

21. Method according to claim 18, wherein either the lower SiGe layer or the lower SiGe layer and the upper Si layer are grown globally in the source and drain regions and the p-channel region.

22. Method according to claim 17, wherein the creation of the state of elastic strain in the material of at least one of the current-carrying channel region and the source and drain regions comprises growing of a stress-liner layer.

23. Method according to claim 22, wherein the stress-liner layer is deposited in such a way that the stress-liner layer is positioned substantially over the source and drain regions and the charge storage layer stack.

24. Method according to claim 22, wherein the stress-liner layer comprises a silicon nitride layer.

25. Method according to claim 22, wherein the stress state of the stress-liner layer is controllable by parameters of the deposition process for deposition of the stress-liner layer.

26. Method according to claim 22, wherein the stress-liner layer is selectively deposited by using a first mask as a first stress-liner specifically tuned for the p-type non-volatile memory device.

27. Method according to claim 26, wherein the stress-liner layer is further selectively deposited by using a second mask as a second stress-liner specifically tuned for an n-type non-volatile memory device.
